(19) United States
(12) Patent Application Publication
(10) Pub. No.: US 2024/0030072 A1
(43) Pub. Date: Jan. 25, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventor: Mingi HONG, Suwon-shi (KR)

(21) Appl. No.: 18/118,775

(22) Filed: Mar. 8, 2023

(30) Foreign Application Priority Data
Jul. 25, 2022 (KR) 10-2022-0091901

(51) Int. Cl. H01L 21/66; H10B 80/00; H01L 21/56

(52) U.S. Cl. CPC H01L 22/12; H10B 80/00; H01L 21/561; H01L 22/30; H01L 2924/1431; H01L 2924/14361; H01L 2924/1433; H01L 24/05

(57) ABSTRACT

A method of manufacturing a semiconductor package includes disposing a buffer die on a support carrier; forming a plurality of memory dies, each of the plurality of memory dies having a body layer and an active layer on a surface of the body layer, wherein the body layer includes a light transmitting region; stacking the plurality of memory dies on the buffer die in a vertical direction to form a semiconductor device; measuring respective distances between the buffer die and the plurality of memory dies by irradiating light on the semiconductor device in the vertical direction; and forming a molding member encapsulating the semiconductor device.

### CROSS-REFRENCE TO RELATED APPLICATION

This application claims priority under 35 U.S.C. § 119 to Korean Patent Application No. 10-2002-0091901, filed on Jul. 25, 2022, in the Korean Intellectual Property Office (KIPO), the disclosure of which is herein incorporated by reference in its entirety.

### TECHNICAL FIELD

Example embodiments relate to a semiconductor package and a method of manufacturing the semiconductor package. More particularly, example embodiments relate to a semiconductor package including a plurality of semiconductor chips and a method of manufacturing the semiconductor package.

### DESCRIPTION OF THE RELATED ART

In a semiconductor product such as a high bandwidth memory (HBM), a stability test is required for measuring a joint gap between a plurality of stacked memory chips. The joint gap measurement may contain errors due to a pressing phenomenon that occurs during a manufacturing process. The errors may arise from variations in chip thickness using indirect measurement methods, such as bond line thickness (RUT) measurement. Direct measurement methods, such as using an infrared interferometer, can be hindered by metal layers present in the active layer of the memory chip located at the top, which may block infrared light. Since infrared light cannot reach the memory chip located at the bottom, it is difficult to measure the error.

### SUMMARY

Example embodiments of the present inventive concept provide a semiconductor package including memory dies having a light transmitting region that enables light to pass through for measuring a joint gap between the memory dies.

Example embodiments of the present inventive concept provide a method of manufacturing the semiconductor package.

According to example embodiments, a method of manufacturing a semiconductor package includes disposing a buffer die on a support carrier; forming a plurality of memory dies, each of the plurality of memory dies having a body layer and an active layer on a surface of the body layer, wherein the body layer includes a light transmitting region; stacking the plurality of memory dies on the butler die in a vertical direction to form a semiconductor device; measuring respective distances between the buffer die and the plurality of memory dies by irradiating light on the semiconductor device in the vertical direction; and forming a molding member encapsulating the semiconductor device. Measuring the respective distances between the buffer die and the plurality of memory dies includes irradiating first light on a first memory die positioned at an uppermost position among the plurality of memory dies, the first memory die having a first body layer and a first active layer, wherein the first body layer includes a first light transmitting region; and measuring a distance between the first memory die and a second memory die through first detected light, wherein the second memory die is positioned immediately below the first memory die among the plurality of memory dies, and wherein the first detected light is formed by the first light sequentially passing through the first light transmitting region in a thickness direction of the first layer, being incident on the second memory die; and reflected from the second memory die.

According to example embodiments, in a method of manufacturing a semiconductor package includes disposing a semiconductor device on a support carrier, wherein the semiconductor includes a buffer die and a plurality of memory dies vertically stacked on the buffer die; irradiating light on a first memory die positioned at an uppermost position among the plurality of memory dies; and passing the light through a first light transmitting region in a first scribe lane region of a first active layer of the first memory die in a thickness direction of the first active layer; detecting first light reflected from a second memory die positioned immediately below the first memory die among the plurality of memory dies; and measuring a distance between the first and second memory dies through the detected first light

According to example embodiments, in a method of manufacturing a semiconductor package, a semiconductor device having a buffer die and a plurality of memory dies vertically stacked on the buffer die is placed on a support carrier. The light is irradiated onto a first memory die positioned at the top of the stacked memory dies. The light is passed through a first light transmitting region in a. scribe: lane region of a first active layer of the first memory die. The light reflected from a second memory die positioned below the first memory die is obtained. A distance between the first and second memory dies is measured through the obtained light.

According to example embodiments; a semiconductor package includes a buffer die; a second memory die vertically stacked on the buffer die, the second memory die having a second upper surface and a second lower surface facing opposite to each other, the second memory die having a second active layer provided on the second lower surface and a second light transmitting region configured to transmit light incident from the second upper surface to the butler die; and a first memory die vertically stacked on the second memory die, the first memory die having a first upper surface and a first lower surface facing opposite to each other, the first memory die haying a first active layer provided on the first lower surface and a first light transmitting region configured to pass light incident from the first upper surface to the second memory die.

Therefore, the light irradiated to the semiconductor device may pass through the first light transmitting region to reach the second memory die. The distance between the first and second memory dies may be directly measured using the light reflected from a lower surface of the first memory die and the light reflected from an upper surface of the second memory die. Since the distance between the first and second memory dies can be directly measured, an error in the distance generated in a semiconductor manufacturing process such as a thermal compression bonding process can be accurately analyzed.

### BRIEF DESCRIPTION OF THE DRAWINGS

Example embodiments of the present inventive concept will be more clearly understood from the following detailed description taken in conjunction with the accompanying drawings. FIGS. 1 to 25 represent non-limiting, example embodiments as described herein.

FIG. 1 is a cross-sectional view illustrating a semiconductor package in accordance with example embodiments.

FIG. 2 is a detailed cross-sectional view illustrating portion ‘A’ in FIG. I.

FIG. 3 is a detailed cross-sectional view illustrating portion ‘B’ in FIG. 2.

FIG. 4 is a plan view illustrating the first and the second memory dies in FIG. 2.

FIG. 5 is a flowchart illustrating a method of manufacturing a semiconductor package in accordance with example embodiments of the present inventive concept.

FIGS. 6 and 7 are cross-sectional views illustrating a process of disposing a buffer die on a support carrier.

FIGS. 8 and 9 are cross-sectional views illustrating a process of stacking a plurality of memory dies on a buffer die.

FIG. 10 is a cross-sectional view illustrating a process of measuring respective distances between a buffer die and a plurality of memory dies.

FIG. 11 is a cross-sectional view illustrating a process of forming a semiconductor device by stacking a plurality of memory dies.

FIGS. 12 to 15 are cross-sectional views illustrating a process of forming a semiconductor package by cutting a semiconductor device along a scribe lane region.

FIG. 16 is a flowchart illustrating a method of measuring each distance between a buffer die and memory dies in FIG. 5.

FIG. 17 is a cross-sectional view illustrating a process of measuring respective distances between a buffer die and a memory die.

FIG. 18 is a detailed cross-sectional view illustrating portion ‘C’ in FIG. 17.

FIG. 19 is a perspective view illustrating first and second memory dies in FIG. 18.

FIG. 20 is a detailed cross-sectional view illustrating portion ‘D’ in FIG. 18.

FIG. 21 is a graph illustrating wavelengths obtained from reflected light in FIG. 20.

FIG. 22 is a plan view illustrating a memory die of a semiconductor package having light transmitting spots in a light transmitting region in accordance with example embodiments of the present disclosure.

FIG. 23 is a cross-sectional view illustrating a semiconductor package in accordance with example embodiments of the present disclosure.

FIG. 24 is a detailed cross-sectional view illustrating portion ‘F’ in FIG. 23.

FIG. 25 is a detailed cross-sectional view illustrating portion ‘G’ in FIG. 24.

### DETAILED DESCRIPTION OF EXAMPLE EMBODIMENTS

Hereinafter, example embodiments will be explained in detail with reference to the accompanying drawings.

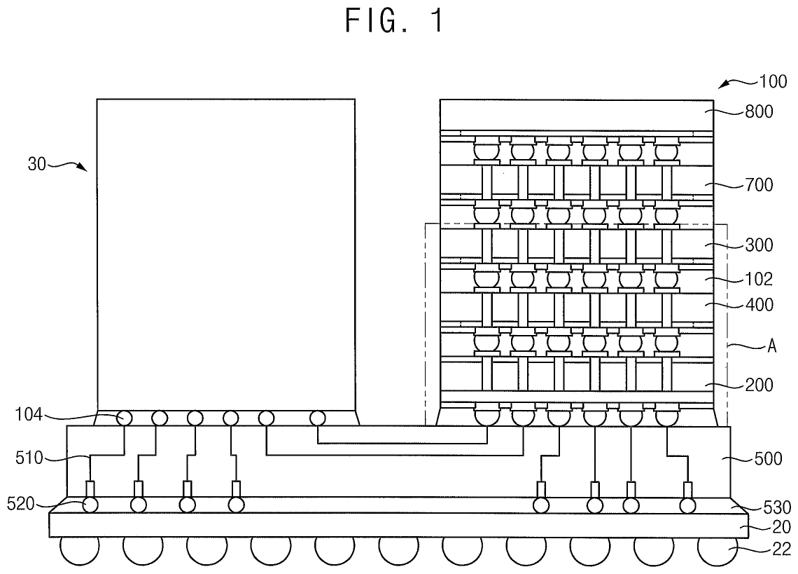

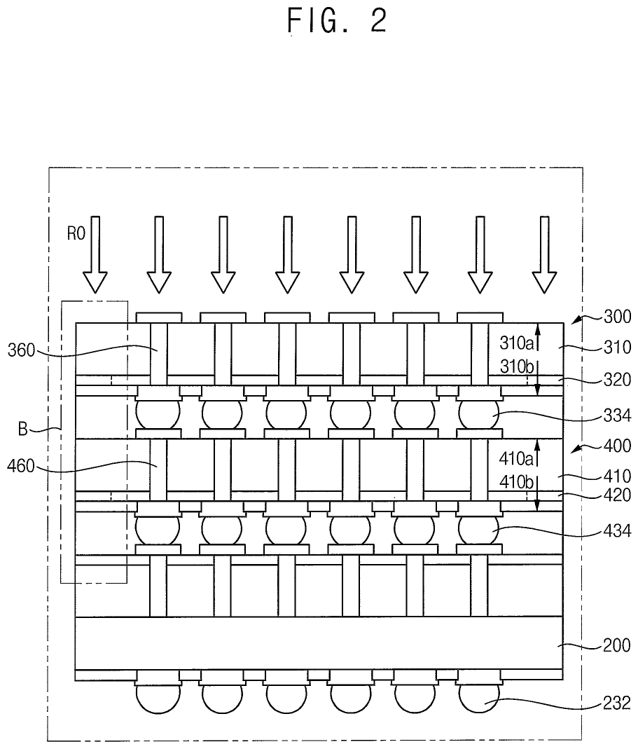

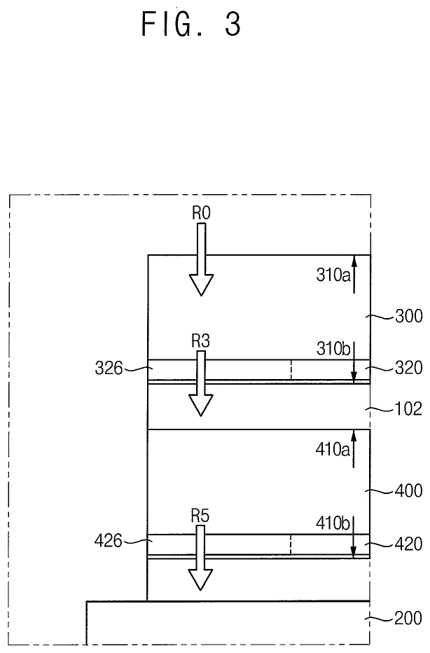

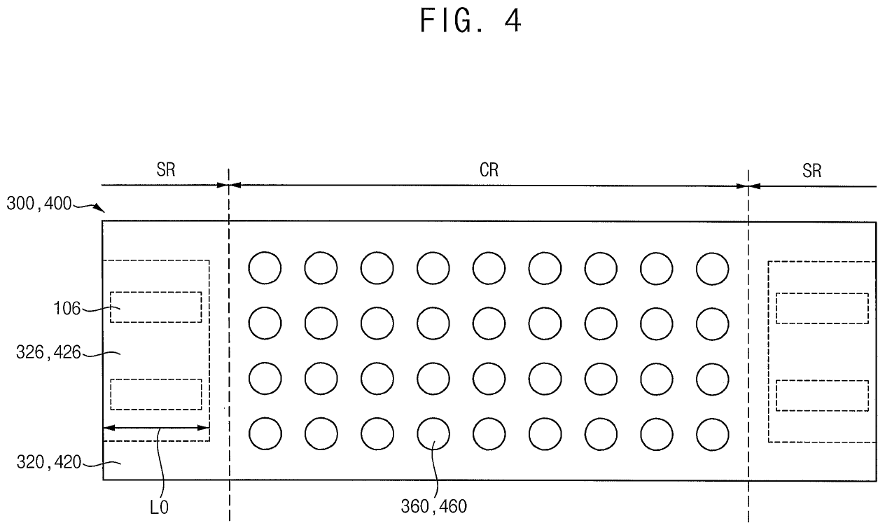

FIG. 1 is a cross-sectional view illustrating a semiconductor package in accordance with example embodiments. FIG. 2 is a detailed cross-sectional view illustrating portion ‘A’ in FIG. 1. FIG. 3 is a detailed cross-sectional view illustrating portion ‘B’ in FIG. 2. FIG. 4 is a plan view illustrating first and second memory dies in FIG. 2.

Referring to FIGS. 1 to 4, a semiconductor package 10 may include a package substrate an electronic component 30 and a semiconductor device 100 disposed on an upper surface of the package substrate 20, and external connection members 22 disposed on a lower surface of the package substrate 20.

In example embodiments, the semiconductor package 10 may be a memory module having a stacked chip structure where a plurality of dies (chips) are stacked. For example, the semiconductor package 10 may include a semiconductor memory device having a 2.5D chip structure where the plurality of dies (chips) are stacked vertically but are not connected directly to each other. For example, the interposer 500 may be disposed between the plurality of dies and electrically connects the plurality of dies with each other. For example, an interposer 500 may be a thin layer of insulating material having conductive pathways on a surface of the interposer 500.

In some embodiments, the electronic component 30 may include a logic semiconductor device, and the semiconductor device 100 may include a memory device. The logic semiconductor device may be an ASIC configured as a host, such as a CPU, GPU, or SoC. The memory device may include a high bandwidth memory (HBM) device. In some embodiments, the semiconductor package 10 may include a semiconductor memory device having a 3D chip structure.

Hereinafter, a case in which the semiconductor package 10 is the semiconductor memory device having the 2.5D chip structure will be described. However, the present disclosure might not be necessarily limited thereto. As illustrated in FIG. 1, the semiconductor memory device may be mounted on the package substrate 20. The semiconductor memory device may include the electronic component 30 (for example, ASIC) which is an electronic component mounted on the interposer 500 and the semiconductor device 100 (for example, HBM) which is the semiconductor device. The ASIC and the HBM may be spaced apart from each other on the interposer 500. The HBM may include a buffer die 200 configured as a logic chip and a plurality of memory dies (chips) 300, 400 sequentially stacked on the buffer die 200. In FIG. 1, two memory dies of the semiconductor device 100 are illustrated, but the number of the memory dies in the present disclosure might not be necessarily limited thereto.

The ASIC may be mounted on the interposer 500 through solder bumps 104, and the buffer die 200 may be mounted on the interposer 500 through the solder bumps 104. For example, the solder bump 104 may include tin (Sn), tin/silver (Sn/Ag), tin/copper (Sn/Cu), or tin/indium (Sn/In).

The buffer die 200 and the first and second memory dies 300, 400 may be electrically connected to each other by through silicon vias (TSVs). The through silicon vias may be electrically connected to each other by solder bumps. The buffer die 200 and the first and second memory dies 300, 400 may communicate signals such as data signals and control signals through the through silicon vias.

Each of the buffer die 200 and the first and second memory dies 300, 400 of the semiconductor device 100 may include a silicon substrate. Circuit patterns may be disposed in an active surface of the silicon substrate. The circuit patterns may include a transistor, a diode, or the like. The circuit patterns may be formed through a water process such as a front-end-of-line (FEOL) process. A front-end-of-line (FEOL) process is a series of steps (such as wafer preparation, lithography, etching, diffusion, deposition, and annealing) in the fabrication of a semiconductor device that takes place before a back-end-of-line (BEOL) process. For example, the FEOL process may be used to create active regions of a semiconductor device and to form source and drain regions of the transistors.

A wiring layer may be disposed on the active surface of the silicon substrate. The wiring layer may be formed on the active surface of the silicon substrate by the back-end-of-line (BEOL) process. The wiring layer may include wirings. For example, the wirings may include aluminum (Al), copper (Cu), tin (Sn), nickel (Ni), gold (Au), platinum (Pt), or an alloy thereof.

An underfill material layer 102 may be disposed between the buffer die 200 and the first and second memory dies 300, 400. For example, the underfill material layer 102 may include a resin material such as an epoxy resin or a silicone resin.

The interposer 500 may include connection wires 510. In some cases, the ASIC and the HBM may be connected to each other through the connection wires 510 disposed inside the interposer 500. In some cases, the ASIC and the HBM may be electrically connected to the package substrate 20 through conductive bumps 520.

As illustrated in FIGS. 2 and 3, the second memory die 400 may be vertically stacked on the buffer die 200, the first memory die 300 may be vertically stacked on the second memory die 400. As illustrated in FIG. 1, the third memory die 700 may be vertically stacked on the first memory die 300, and the fourth memory die 800 may be vertically stacked on the third memory die 700. Each of the distances between the buffer die 200 and the first to fourth memory dies 300, 400, 700, 800 may be measured by applying irradiated light R0 to the first memory die 300. For example, the first memory die 300 allows the irradiated light R0 incident from the first upper surface 310a to pass through and reach the first lower surface 310b.

According to the present disclosure, a plurality of memory dies may be sequentially stacked on the buffer die 200, and the number of the plurality of memory chips sequentially stacked on the buffer die 200 is not limited to four. Hereinafter, a case in which the semiconductor device 100 includes first to fourth memory dies 300, 400, 700, 800 will be described. Also, a case in which the respective distances between the first and second memory dies 300, 400 are measured will be described. However, the present disclosure might not be necessarily limited to including the first to fourth memory dies 300, 400, 700, 800 and not be necessarily limited to measuring the distance between the first and second memory dies 300, 400.

The irradiated light R0 may have a wavelength for measuring a distance between the first to fourth memory dies 300, 400, 700, 800 and the buffer die 200 respectively. The irradiated light R0 may be emitted from a time domain spectroscopy (TDS). The time domain spectrometer may be a device that measures the distance between objects by detecting reflected light when emitted light collides with the objects and is reflected.

The irradiated light R0 may include a wavelength of infrared radiation. According to some embodiments, as the wavelength of the infrared radiation is within a range of 0.75 μm to 1000 μm, the distance between the first to fourth memory dies 300, 400, 700, 800 and the buffer die 200 may be more accurately measured through the time domain spectrometer using the light having the infrared wavelength.

In example embodiments, the first memory die 300 may include a first body layer 310. The first body layer 310 may have a first upper surface 310a and a first lower surface 310b facing opposite to each other. The first memory die 300 may include a first active layer 320 disposed under the lower surface 310b. The first active layer 320 may include circuit patterns and a wiring layer.

The first memory die 300 may be electrically connected to the buffer die 200, the second memory die 400, and the like through one or more of the first through silicon vias 360. The first through silicon vias 360 may be electrically connected to each other by first solder bumps 334. The first memory die 300 may communicate signals such as data signals and control signals through the first through silicon vias 360s.

The first active layer 320 of the first memory die 300 may have a first light transmitting region 326 for allowing the irradiated light R0 incident from the first upper surface 310a to pass through and reach the first lower surface 310b. The first memory die 300 may include a die region and a scribe lane region SR surrounding the die region. The scribe lane region SR may be formed by removing a portion of the scribe lane region SR in a wafer level through a dicing process. The scribe lane region SR may have a rectangular ring shape. For example, the rectangular shape may have a predetermined width extending from an outer surface of the first memory die 300. The first light transmitting region 326 may be disposed in the scribe lane region SR. For example, the first light transmitting region 326 may be a region that does not include at least one of the metal materials in the first active layer 320. The first light transmitting region 326 may be a light transmitting region that transmits the light through the first memory die 300 in a thickness direction thereof. The metal material may include aluminum (Al), copper (Cu), tin (Sn), nickel (Ni), gold (Au), platinum (Pt), or an alloy thereof.

The first active layer 320 of the first memory die 300 may comprise a first light transmitting region 326, the first light transmitting region 326 allowing the irradiated light R0 incident on the first upper surface 310a to pass through and reach the first lower surface 310b. The light R3 passing through the first memory die 300 may reach at the second memory die 400 disposed below the first memory die 300. The distance between the first memory die 300 and the second memory die 400 may be measured through the light reflected from the first lower surface 310b of the first memory die 300 and the light reflected from the second memory die 400.

In example embodiments, the second memory die 400 may include a second body layer 410. The second body layer 410 may have a second upper surface 410a and a second lower surface 410b facing opposite to each other. The second memory die 400 may include a second active layer 420. The second active layer 420 may include circuit patterns and a wiring layer.

The second memory die 400 may be electrically connected to the buffer die 200, the first memory die 300, and the like through one or more of the plurality of second through silicon vias 460. The plurality of second through silicon vias 460 may be electrically connected to each other by second solder bumps 434. The second memory die 400 may communicate signals such as data signals and control signals through the second through silicon vias 460.

The second active layer 420 of the second memory die 400 may have a second light transmitting region 426 for passing the light R3 incident from the second upper surface 410a to the second lower surface 410b. The second light transmitting region 426 may be provided in the scribe lane region SR. For example, the second light transmitting region 426 may be a region that does not include at least one of the metal materials in the second active layer 420. The metal material may include aluminum (Al); copper (Cu), tin (Sn), nickel (Ni), gold (Au), platinum (Pt), or an alloy thereof.

The second active layer 420 of the second memory die 400 may comprise the second light transmitting region 426 that allows the light R3 incident on the second upper surface 410a to pass through and reach the second lower surface 410b. The light R5, after passing through the second memory die 400, may reach the buffer die 200 positioned immediately below the second memory die 400. The distance between the second memory die 400 and the buffer die 200 may be measured through the light reflected from the second lower surface 410b of the second memory die 400 and the light reflected from the buffer die 200.

As illustrated in FIG. 4, the first light transmitting region 326 of the first memory die 300 and the second light transmitting region 426 of the second memory die 400 may have regions overlapping each other in a plan view. The light may pass through the semiconductor device 100, including the overlapping regions, in the vertical direction. The light may be reflected by the first and second memory dies 300, 400 and the buffer die 200, respectively, while passing through the overlapping regions, and each of the distances between the first and second memory dies 300, 400 and the buffer die 200 may be measured through the reflected lights.

For example, the first and second light transmitting regions 326, 426 may be provided in the scribe lane region SR. The first and second light transmitting regions 326, 426 may remove from the semiconductor device 100 in a sawing process for manufacturing the semiconductor package.

The first light transmitting region 326 may extend horizontally from a side surface of the first memory die 300 in the first active layer 320 to have a predetermined length L0. For example, the predetermined length L0 may be within a range of 25 μm to 35 μm.

The second light transmitting region 426 may extend horizontally from a side surface of the second memory die 400 in the second active layer 420 to have a predetermined length L0. For example, the predetermined length L0 may be within a range of 25 μm to 35 μm.

Hereinafter, a method of manufacturing the semiconductor package of FIG. 1 including measuring a joint gap between the buffer die and the memory dies will be described.

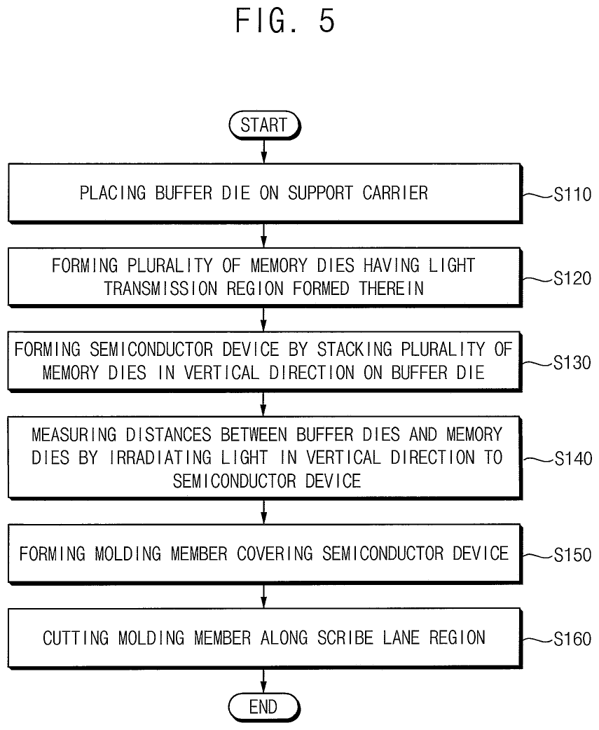

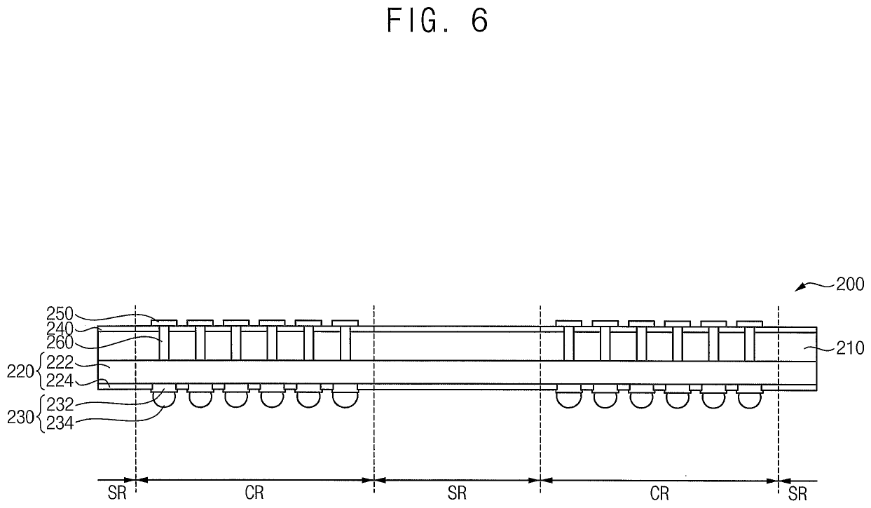

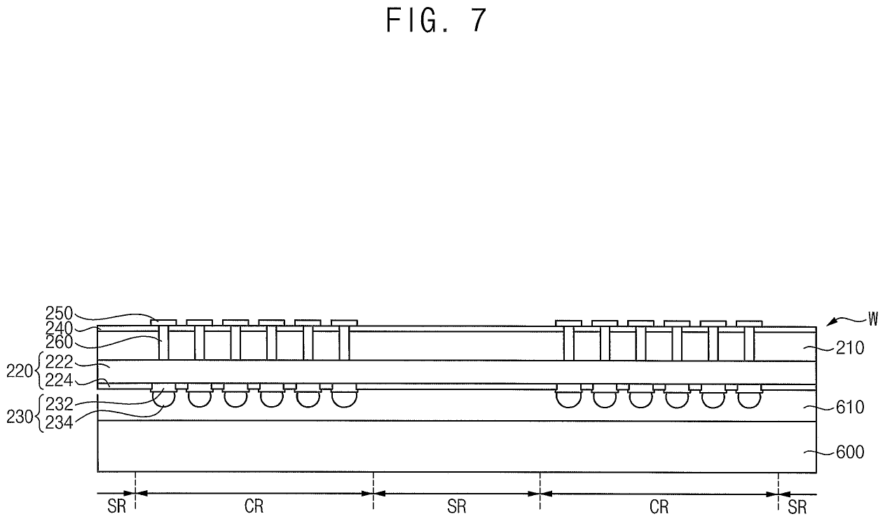

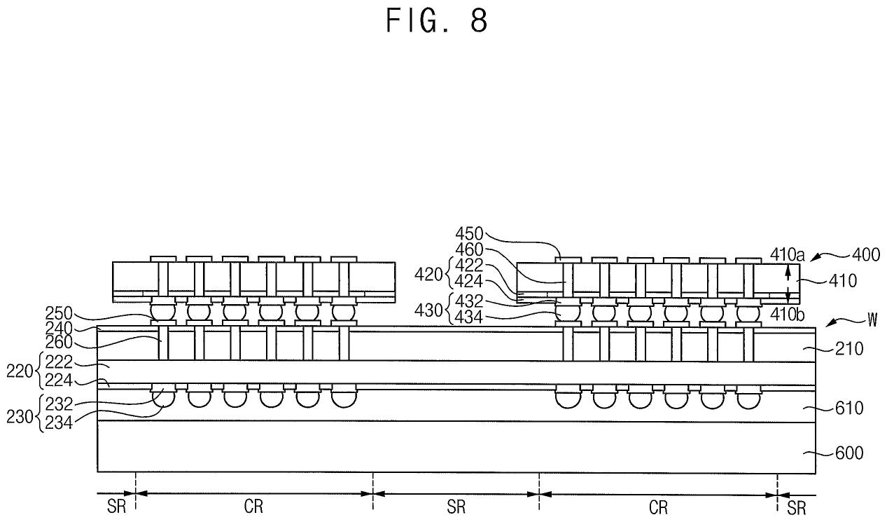

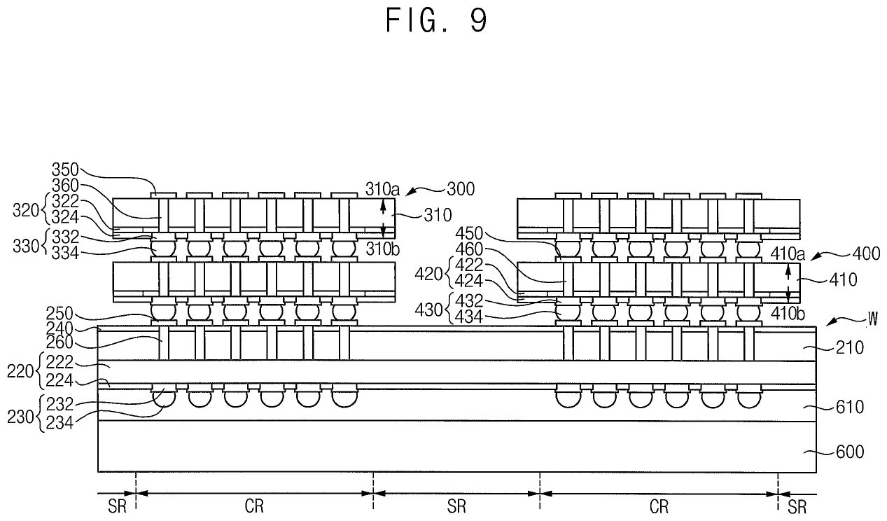

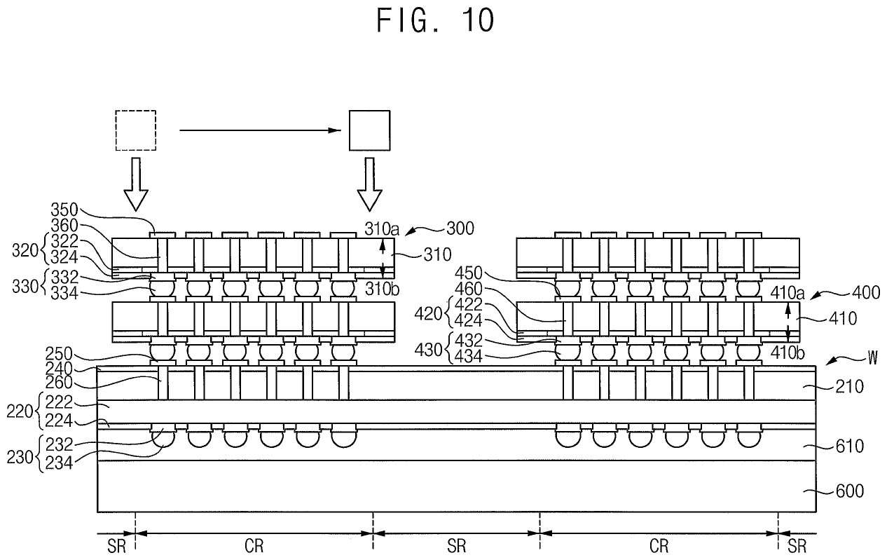

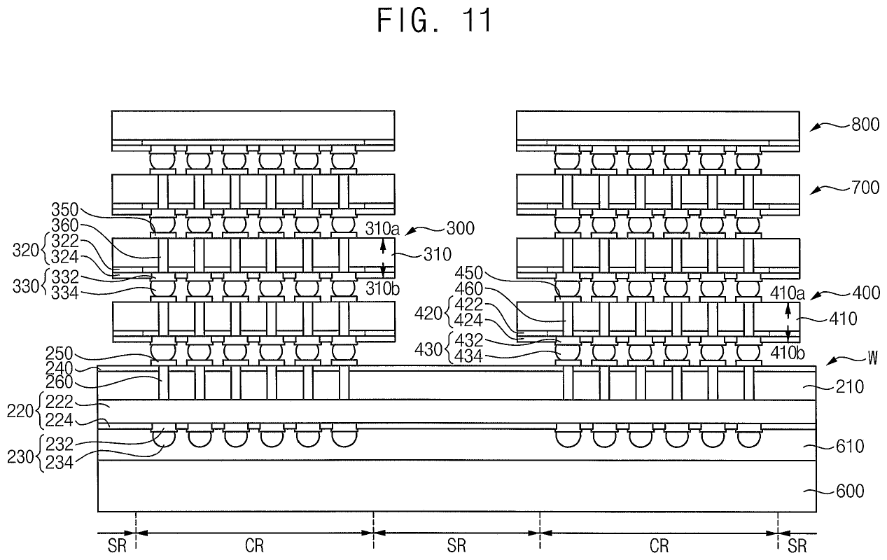

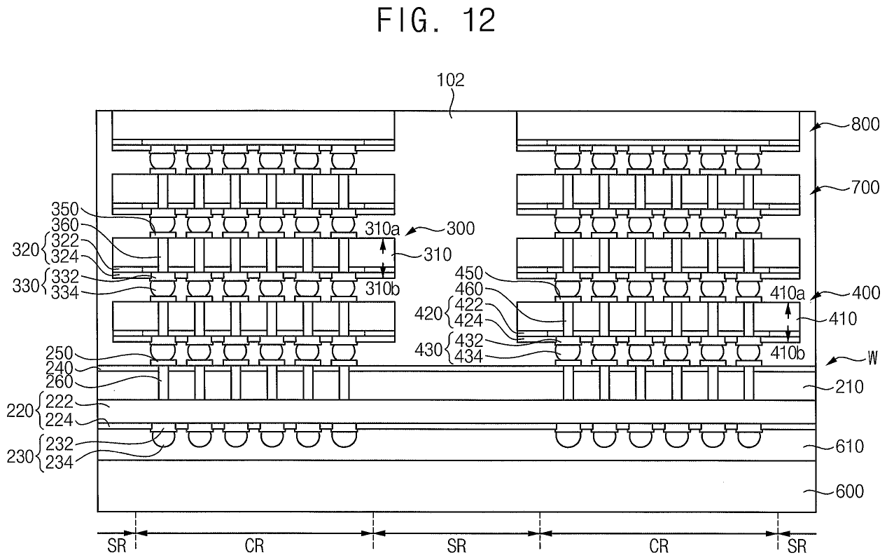

FIG. 5 is a flowchart illustrating a method of manufacturing a semiconductor package in accordance with example embodiments of the inventive concept. FIGS. 6 and 7 are cross-sectional views illustrating processes of disposing a buffer die on a support carrier. FIGS. 8 and 9 are cross-sectional views illustrating processes of stacking a plurality of memory dies on a buffer die. FIG. 10 is a cross-sectional view illustrating a process of measuring respective distances between the buffer die and the memory dies. FIG. 11 is a cross-sectional view illustrating a process of forming a semiconductor device by stacking a plurality of memory dies. FIGS. 12 to 15 are cross-sectional views illustrating a process of forming a semiconductor package by cutting a semiconductor device along a scribe lane region.

Referring to FIGS. 1 to 15, first, a buffer die 200 may be disposed on a support carrier 600 (S110).

In example embodiments, as illustrated in FIG. 6, a base water W may be formed, where the base wafer W includes a plurality of buffer dies 200, and a plurality of through silicon vias (TSVs) 260 may be formed in the plurality of buffer dies 200. The base wafer W may be formed by providing buffer dies 200 with the through silicon vias 260 at a wafer level. A size (length or width) of a chip area of the base wafer W may correspond to CR. A size (size or width) of a scribe lane region between the buffer dies 200 of the base wafer W may correspond to SR.

Two buffer dies 200 are illustrated in the base water W in FIG. 6, however, the present disclosure might not be necessarily limited thereto, and in some examples, tens to hundreds of butler dies 200 may be formed in the base wafer W. For example, test terminals 106 may be formed in the scribe lane region SR. The test terminals 106 may apply a voltage to an interior of a semiconductor device 100 to measure a capacitance within the semiconductor device 100 to perform a test. The first and second light transmitting regions 326, 426 may be formed in the scribe lane region SR.

The buffer die 200 of the base wafer W may include a body layer 210, an active layer 220, a through silicon via 260 a connection member 230, a protective layer 240, and a chip pad 250. The body layer 210 may include a silicon substrate.

The active layer 220 may be formed on one surface of the body layer 210. The active layer 220 may include an integrated circuit layer formed on the silicon substrate and an interlayer insulating layer covering the integrated circuit layer. The active layer 220 may include an intermetallic insulating layer 222 and a passivation layer 224. A multilayer wiring pattern may be formed in the intermetallic insulating layer 222.

The plurality of through silicon vias 260 may connect to the multilayer wiring pattern of the active layer 220 by passing through the body layer 210. The connection member 230 may include a bump pad 232 and a solder bump 234. In some cases, the bump pad 232 may be formed of a conductive material. In some cases, the bump pad 232 may be formed on the passivation layer 224 and may be electrically connected to the multilayer wiring pattern in the active layer 220. The bump pad 232 may be electrically connected to the plurality of through silicon vias 260 through the multilayer wiring pattern. The connection member 230 may be electrically connected to one surface of the through silicon via 260.

The bump pad 232 may be formed of aluminum (Al), copper (Cu), or the like, and may be formed through pulse plating or DC plating. Solder bumps 234 may be formed on the bump pads 232. The solder bump 234 may be formed of a conductive material, for example, copper (Cu), aluminum (Al), gold (Au), solder, or the like. However, the material of the solder bump 234 might not be necessarily limited thereto. For example, the solder bumps 234 may include micro bumps (uBump).

The protective layer 240 may be formed on an upper surface of the body layer 210 and may be formed of an insulating material. For example, the insulating material may cover the body layer 210 from the exterior. The protective layer 240 may be formed of an oxide film or a nitride film, or may be formed of a double layer of an oxide film and a nitride film. The protective layer 240 may be formed of an oxide film, for example, a silicon oxide film (SiO2) using a high-density plasma chemical vapor deposition (HDP-CVD) process.

The chip pad 250 may be formed on the protective layer 240 and may be electrically connected to the plurality of through silicon vias 260. The chip pad 250 may be electrically connected to the plurality of through silicon vias 260 on the other surface of the through silicon via 260. The chip pad 250 may be formed of aluminum or copper, such as the bump pad 232.

As illustrated in FIG. 7, the base wafer W may be disposed on the supporting carrier 600. An adhesive member 610 may be formed on the support carrier 600. The support carrier 600 may be formed of silicon, germanium, silicon-germanium, gallium-arsenide (GaAs), glass, plastic, a ceramic substrate, or the like. The support carrier 600 may be formed of a silicon substrate or a glass substrate. The adhesive member 610 may be formed of NCF (Non-Conductive Film), ACF (Anisotropic Conductive Film), UV film, instant adhesive, thermosetting adhesive, laser curing adhesive, ultrasonic eating adhesive, NCP (Non-Conductive Paste), etc.

The base water W may be adhered to the support carrier 600 through the adhesive member 610. The base wafer W may be adhered such that the connecting member 230 faces the support carrier 600. The support carrier 600 may be prepared before the base wafer W is prepared. In some embodiments, the support carrier 600 may be prepared after the base wafer W is prepared and before the base wafer W is adhered to the support carrier 600.

Then, forming a plurality of memory dies, such as the first and second memory dies 300, 400, in which the first and second light transmitting regions 326, 426 are formed (S120), and forming the semiconductor device 100 by stacking the plurality of memory dies, such as the first and second memory dies 300, 400, on the butler die 200 in a vertical direction (S130).

In example embodiments, the second memory die 400 may be stacked on the buffer die 200.

As illustrated in FIG. 8, the second memory die 400 may include a second body layer 410, a second active layer 420, a second through silicon via 460, a second connection member 430, and a second chip pad 450.

The second body layer 410 may include a second upper surface 410a and a second lower surface 410b facing opposite to each other. The second upper surface 410a of the second body layer 410 may be exposed to the exterior. The second upper surface 410a of the second body layer 410 may be a surface exposed to the exterior of the silicon substrate on which the integrated circuit layer is formed. The protective layer may be formed on the surface exposed to the exterior of the silicon substrate.

The second active layer 420 may be formed on the second lower surface 410b of the second body layer 410. The second active layer 420 may include the silicon substrate, the integrated circuit layer formed on the silicon substrate, and the interlayer insulating layer covering the integrated circuit layer. The second active layer 420 may include a second intermetallic insulating layer 422 and a second passivation layer 424. The multilayer wiring pattern may be formed inside the second intermetallic insulating layer 422.

The second active layer 420 may include the second light transmitting region 426. For example, the second light transmitting region 426 may be a region that does not include at least one of the metal materials inside the second active layer 420. The metal material may include aluminum (Al), copper (Cu), tin (Sn), nickel (Ni), gold (Au), platinum (Pt), or an alloy thereof. For example, the second light transmitting region 426 may be formed by not forming a pattern or applying the metal material in a manufacturing process of the second active layer 420. In some embodiments, the second light transmitting region 426 may be formed by removing the metal materials from the second active layer 420 through an etching process.

The second through silicon via 460 may pass through the second body layer 410 and may connect to the multilayer wiring pattern of the second active layer 420. The second connection member 430 may include a second bump pad 432 and a second solder bump 434. The second bump pad 432 may be formed of the conductive material on the second passivation layer 424, and may be electrically connected to the multilayer wiring pattern in the second active layer 420. The second bump pad 432 may be electrically connected to the second through silicon via 460 through the multilayer wiring pattern. The second connection member 430 may be electrically connected to one surface of the second through silicon via 460. The second bump pad 432 may be formed of the same material as the bump pad 232 of the buffer die 200.

The second solder bumps 434 may be formed on the second bump pads 432. The second solder bump 434 may be formed of the conductive material. The second solder bumps 434 may be formed of copper (Cu), aluminum (Al), gold (Au), solder, or the like, like the solder bumps 234 of the buffer die 200.

A stacked chip may be formed by stacking the second memory die 400 on an upper surface of each of the buffer dies 200. The stacked chip may be formed by bonding the second connection member 430 of the second memory die 400 to the chip pad 250 of the buffer die 200 through a thermal compression process. The second connection member 430 may be connected to the chip pad 250 of the buffer die 200. Accordingly, the multilayer wiring pattern of the second memory die 400 may be electrically connected to the plurality of through silicon vias 260 of the buffer die 200 through the second connection member 430.

When an arrangement of the second connection member 430 of the second memory die corresponds to an arrangement of the chip pad 250 of the buffer die 200, the second memory die 400 may be stacked on the buffer die 200. The second memory die 400 may be a chip different from the buffer die 200. In some embodiments, the second memory die 400 may be a chip of the same type as the butler die 200.

The second memory die 400 may be obtained by cutting the same base wafer as the buffer die 200. In this case, the through silicon via may not be formed in the second memory die 400. In some embodiments, the through silicon via may be formed in the second memory die 400.

After stacking the second memory dies 400 on the upper surfaces of each of the buffer dies 200 to form the stacked chip, the capacitance within the stacked chip may be measured through the test terminal 106 disposed on the scribe lane region SR of the second memory die 400. The capacitance measurements may be performed in-line during the manufacturing process.

In example embodiments, the first memory die 300 may be stacked on the second memory die 400.

As illustrated in FIG. 9, the first memory die 300 may include a first body layer 310, a first active layer 320, a first through silicon via 360, a first connection member 330, and a first chip pad 350.

The first body layer 310 may include a first upper surface 310a and a first lower surface 310b facing opposite to each other. The first upper surface 310a of the first body layer 310 may be exposed to the exterior. The first upper surface 310a of the first body layer 310 may be a surface exposed to the exterior of the silicon substrate on which the integrated circuit layer is formed. The protective layer may be formed on the surface exposed to the exterior of the silicon substrate.

The first active layer 320 may be formed on the first lower surface 310b of the first body layer 310. The first active layer 320 may include the silicon substrate, the integrated circuit layer formed on the silicon substrate, and the interlayer insulating layer coveting the integrated circuit layer. The first active layer 320 may include a first intermetallic insulating layer 322 and a first passivation layer 324. The multilayer wiring pattern may be formed in the first intermetallic insulating layer 372.

The first active layer 320 may include a first light transmitting region 326. For example, the first light transmitting region 326 may be a region that does not include at least one of the metal materials in the first active layer 320. The metal material may include aluminum (Al), copper (Cu), tin (Sn), nickel (Ni), gold (Au), platinum (Pt), or an alloy thereof. For example, the first light transmitting region 326 may be formed by a method of not forming a pattern and not applying the metal material in a manufacturing process of forming a semiconductor device of the first active layer 320. In some embodiments, the first light transmitting region 326 may be formed by removing the metal materials from the first active layer 320 through an etching process.

The first through silicon via 360 may pass through the first body layer 310 and may connect to the multilayer wiring pattern of the first active layer 320 The first connection member 330 may include a first bump pad 332 and a first solder bump 334. The first bump pad 332. may be formed of the conductive material on the first passivation layer 324, and may be electrically connected to the multilayer wiring pattern in the first active layer 320. The first bump pad 332 may be electrically connected to the first through silicon via 360 through the multilayer wiring pattern. The first connection member 330 may be electrically connected to one surface of the first through silicon via 360. The first bump pad 332 may be formed of the same material as the bump pad 232 of the buffer die 200.

The first solder bumps 334 may be formed on the first bump pads 332. The first solder bump 334 may be formed of a conductive material. The first solder bump 334 may be formed of copper (Cu), aluminum (Al), gold (Au), solder, or the like, like the solder bump 234 of the buffer die 200.

The stacked chip may be formed by stacking the first memory dies 300 on the second upper surfaces 410a of each of the second memory dies 400. The stacked chip may be formed by bonding the first connection member 330 of the first memory die 300 to the second chip pad 450 of the second memory die 400 through the thermal compression process. The first connection member 330 may be connected to the second chip pad 450 of the second memory die 400. Accordingly, the multilayer wiring pattern of the first memory die 300 may be electrically connected to the second through silicon via 460 of the second memory die 400 through the first connection member 330.

When an arrangement of the first connection member 330 of the first memory die 300 corresponds to an arrangement of the second chip pad 450 of the second memory die 400, the first memory die 300 may be stacked on the memory die 400. The first memory die 300 may be a chip different from the second memory die 400. In some embodiments, the first memory die 300 may be a chip of the same type as the second memory die 400.

The first memory die 300 may be obtained by, cutting the same base wafer as the buffer die 200. In this case, the through silicon via may not be formed in the first memory die 300. In some embodiments, the through silicon via may be formed in the first memory die 300.

After stacking the first memory dies 300 on the second upper surfaces 410a of each of the second memory dies 400 to form the stacked chip, the capacitance within the stacked chip may be measured through the test terminal 106 disposed on the scribe lane region SR of the first memory die 300. The capacitance measurements may be performed in-line during the manufacturing process.

Then, the respective distances between the buffer die 200 and the first and second memory dies 300, 400 may be measured by irradiating light R0 on the semiconductor device 100 in the vertical direction (S140).

In example embodiments, the second memory die 400 may be vertically stacked on the buffer die 200, and the first memory die 300 may be stacked on the second memory die 400 in the vertical direction. Each of the distances between the stacked buffer die 200 and the first and second memory dies 300, 400 may be measurwed by the irradiated light R0.

The measuring the respective distances between the buffer die 200 and the first and second memory dies 300, 400 (S130) may include irradiating the irradiated light R0 on the first memory die 300 disposed at the top of the stacked memory dies, passing the light from the scribe lane region SR to the first light transmitting region 326 disposed in the first active layer 320 of the first memory die 300, detecting the light R3 reflected from the second memory die 400 located under the first memory die 300, and measuring the distance between the first and second memory dies 300, 400 through the obtained light R3.

A third memory die may be additionally disposed between the buffer die 200 and the second memory die 400. In this case, the measuring the respective distances between the buffer die 200 and the first and second memory dies 300, 400 (S130) may further include passing the light from the scribe lane region SR to the second light transmitting region 426 disposed in the second active layer 420 of the second memory die 400, detecting the light reflected from the third memory die located under the second memory die 400, and measuring the distance between the first and second memory dies 300, 400 through the obtained light.

As illustrated in FIG. 10, the irradiated light R0 may be irradiated onto the first upper surface 310a of the first memory die 300. The irradiated light R0 may be reflected from the first and second memory dies 300, 400 and the buffer die 200. The irradiated light R0 may have a wavelength for measuring the distance between the first and second memory dies 300, 400 and the buffer die 200. The irradiated light R0 may be emitted from a time domain spectroscopy (TDS). The time domain spectrometer may be a device that measures the distance between objects by detecting reflected light when emitted light collides with the objects and is reflected.

The irradiated light R0 may include a wavelength of infrared radiation. Since the wavelength of the infrared radiation is within a range of 0.75 μm to 1000 μm, the distance between the first and second memory dies 300, 400 and the buffer die 200 may be more accurately measured through the time domain spectrometer using the light having the infrared wavelength.

Then, a molding member encapsulating the semiconductor device 100 may be formed (S150), and the semiconductor device 100 may be cut along the scribe lane region to form the semiconductor package 10 (S160).

In example embodiments, third and fourth memory dies 700, 800 may be stacked on the first memory die 300.

As illustrated in FIG. 11, the third and fourth memory dies 700, 800 may be sequentially stacked on the first memory die 300. The third and fourth memory dies 700, 800 may be stacked after the measurement of the distance between the first and second memory dies 300, 400 is completed. In some embodiments, the third and fourth memory dies 700, 800 may be stacked on the buffer die 200 together with the first and second memory dies 300, 400. In this case, the distance between the third and fourth memory dies 700, 800 and the distance between the first and third memory dies 300, 700 may be measured together with the distance between the first and second memory dies 300, 400.

In example embodiments, the semiconductor device 100 may be cut along the scribe lane region SR.

As illustrated in FIG. 12, an underfill material layer 102 and the molding member may be formed to fill at least a part, of the connection portions of the first to fourth memory dies 300, 400, 700, 800 of the semiconductor device 100.

The underfill material layer 102 may fill at least a part of the connection portion between the buffer die 200 and the second memory die 400, that is, a portion where the chip pad 250 of the buffer die 200 and the second connection member 430 of the second memory die 400 are connected. The underfill material layer 102 may fill the at least a part of the connection portion between the first memory die 300 and the second memory die 400, that is, the second chip pad 450 of the second memory die 400 and the first connection member 330 of the first memory die 300 are connected.

The underfill material layer 102 may be formed of an underfill resin such as an epoxy resin, and may include silica filler or a flux. The underfill material layer 102 may be formed of a different material or the same material as that of the molding member. The molding member may be formed of a polymer such as resin. For example, the molding member may be formed of epoxy molding compound (EMC).

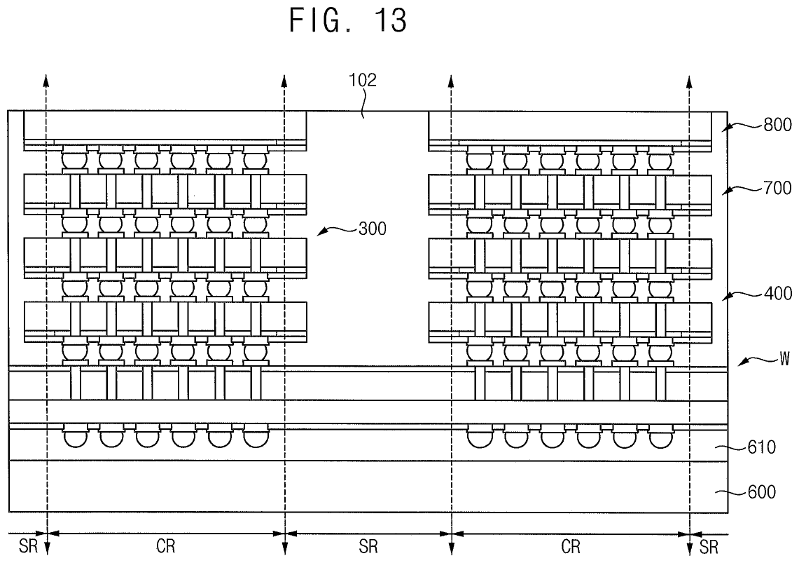

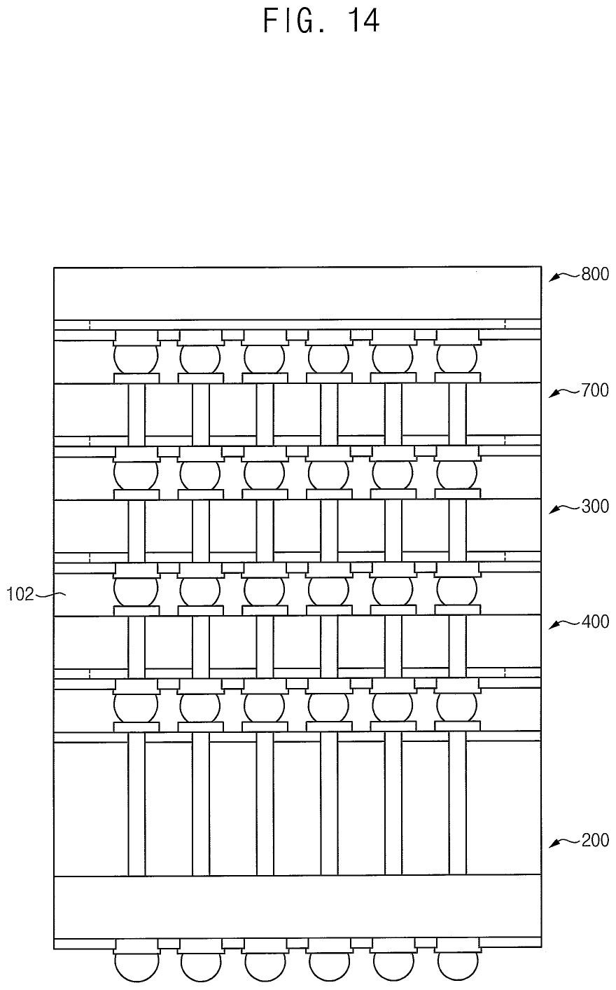

As illustrated in FIGS. 13 and 14, the base wafer W and the sealing material may be separated into the respective chip stacked semiconductor devices 100 through a sawing process or the like. The adhesive member may be removed by the sawing process.

When the scribe lane region SR is cut in the sawing process, a portion of the first and second light transmitting regions 326, 426 may remain in the scribe lane region SR of the final product of the chip stacked semiconductor package 10. In some embodiments, the first and second light transmitting regions 326, 426 may be completely removed.

Each chip stacked semiconductor device 100 may be completed by removing the support carrier 600 and the adhesive member 610. The removal of the support carrier 600 and the adhesive member 610 may be performed sequentially or may be performed simultaneously. When each chip stacked semiconductor device 100 is formed through a cutting process, both sides of each of the buffer die 200 and the first and second memory dies 300, 400 may be exposed. When the chip stacked semiconductor device 100 is mounted on an interposer 500 or the package substrate 20 and molded again, additional molding members may be respectively coupled and attached to the exposed both sides of the buffer die 200 and the first and second memory dies 300 and 400.

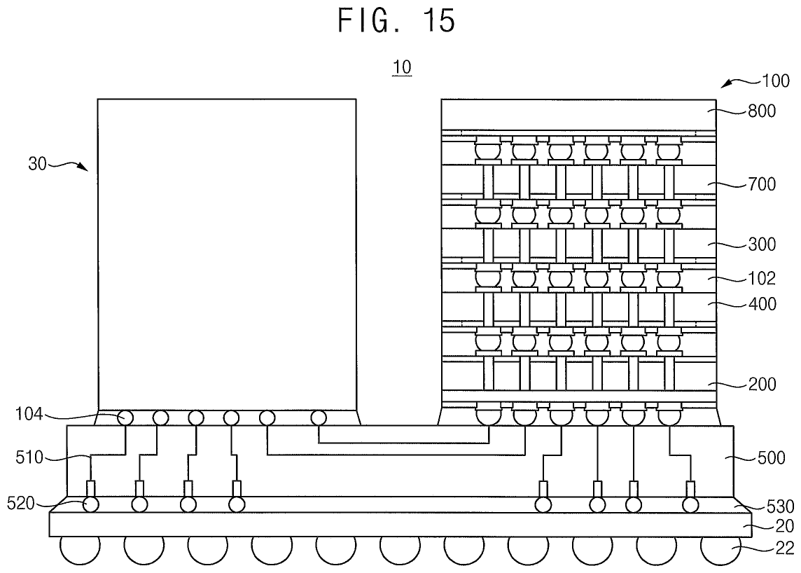

As illustrated in FIG. 15, the semiconductor device 100 may be mounted on the interposer 500. The semiconductor device 100 may be mounted on the interposer 500 to be spaced apart from the electronic component 30. Subsequently, a sealing member 530 covering the semiconductor device 100 and the electronic component 30 may be formed on the interposer 500. The electronic component 30 may include a logic semiconductor device, and the semiconductor device 100 may include a memory device. The logic semiconductor device may be an ASIC configured as a host, such as a CPU, GPU, or SoC. The memory device may include a high bandwidth memory (HBM) device.

In example embodiments, the semiconductor device 100 and the electronic component 30 may be mounted on the interposer 500 by a flip chip bonding method. The bump pads 232 of the buffer die 200 of the semiconductor device 100 may be electrically connected to bonding pads of the interposer 500 by conductive bumps 520. For example, the conductive bumps 520 may include micro bumps (uBump).

For example, the sealing member 530 may include the epoxy mold compound (EMC). The sealing member 530 may be formed to expose the upper surfaces of the semiconductor device 100 and the electronic component 30.

The interposer 500 may be mounted on the package substrate 20 through conductive bumps 520. The interposer 500 may be attached to the package substrate 20 by the thermal compression process.

An adhesive material may be underfill between the interposer 500 and the package substrate 20, A planar area of the interposer 500 may be smaller than a planar area of the package substrate 20.

Then, the semiconductor package 10 of FIG. 1 may be completed by forming external connection members 22 such as solder balls on external connection pads on the lower surface of the package substrate 20.

Hereinafter, measuring the respective distances between the buffer die 200 and the first and second memory dies 300, 400 through the light will be described in detail.

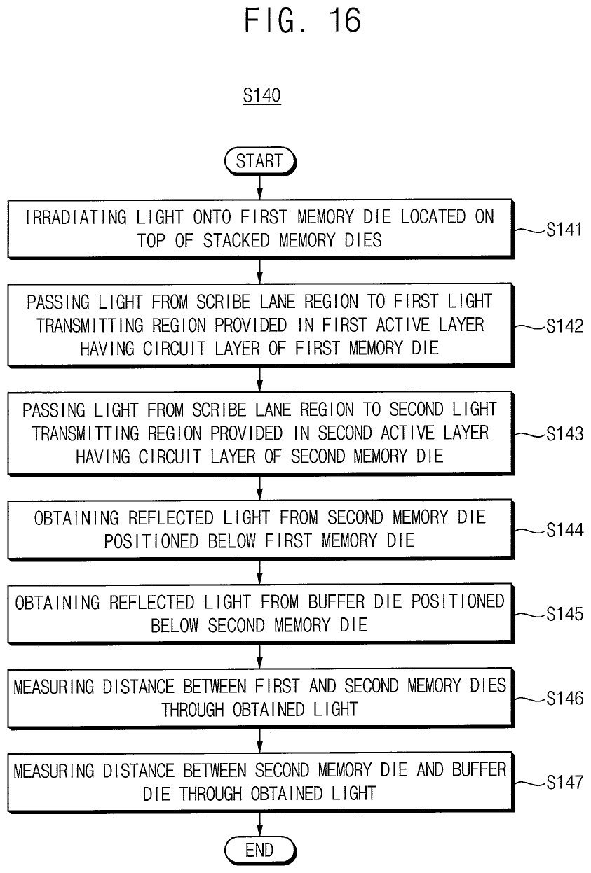

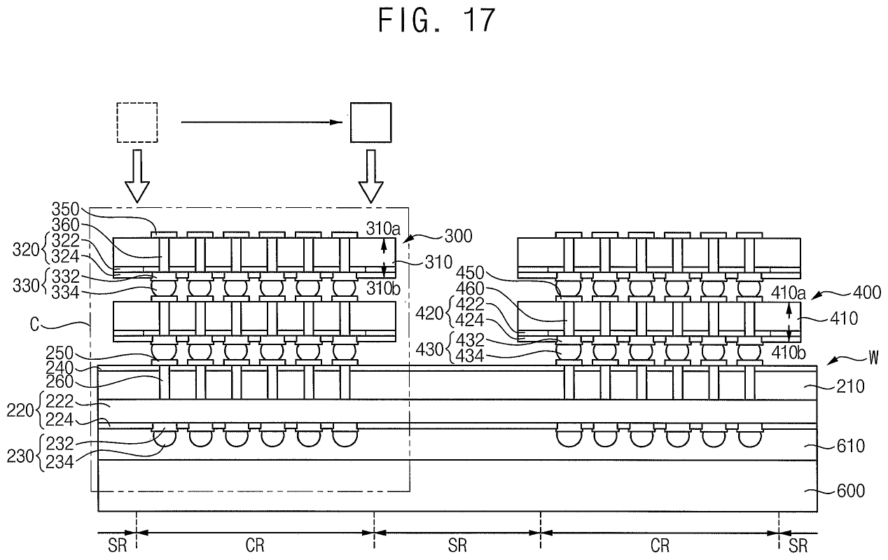

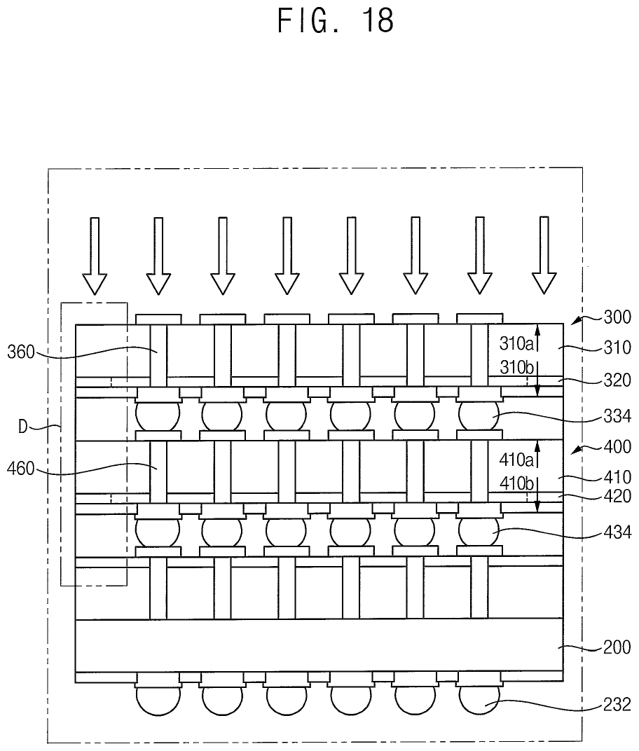

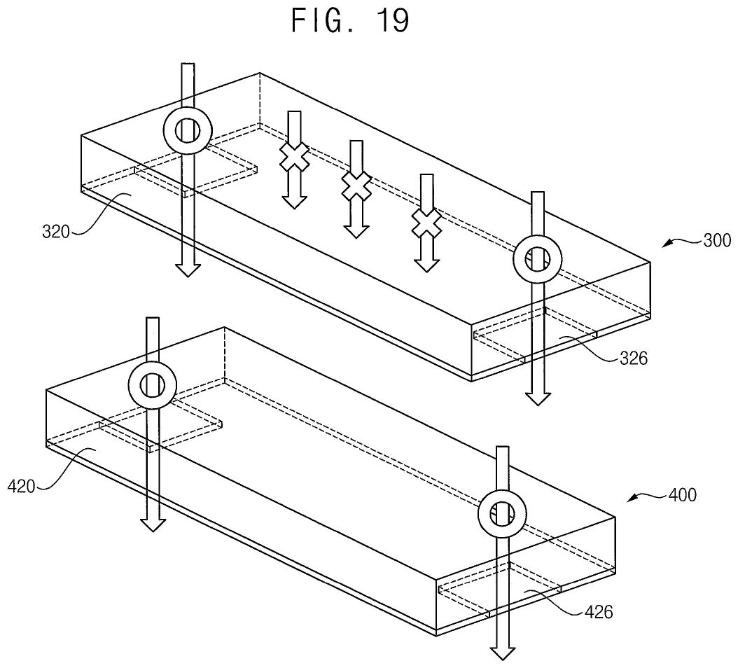

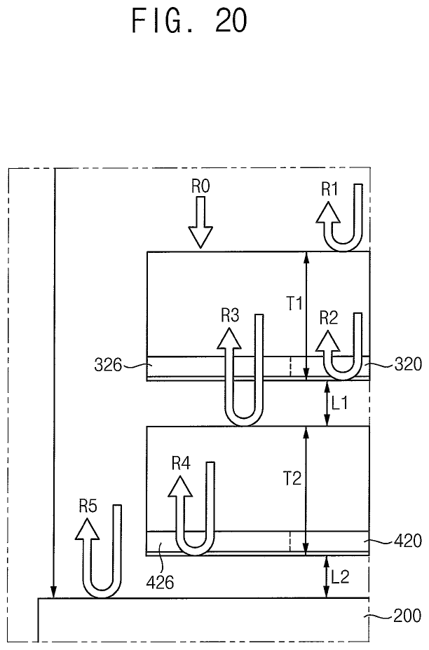

FIG. 16 is a flowchart illustrating a method of measuring each distance between a buffer die and memory dies in FIG. 5, FIG. 17 is a cross-sectional view illustrating a process of measuring respective distances between a buffer die and a memory die. FIG. 18 is a detailed cross-sectional view illustrating portion ‘C’ in FIG. 17. FIG. 19 is a perspective view illustrating first and second memory dies in FIG. 18. FIG. 20 is a detailed cross-sectional view illustrating portion ‘D’ in FIG. 18.

Referring to FIGS. 16 to 21, the respective distances between the stacked buffer die 200 and the first and second memory dies 300, 400 may be measured by the irradiated light. The irradiated light may pass through the first and second light transmitting regions 326, 426 provided in each of the first and second memory dies 300, 400.

First, the irradiated light R0 may be irradiated onto the first memory die 300 disposed at the top of the stacked memory dies (S141).

In example embodiments, as illustrated in FIG. 17, the irradiated light R0 may be irradiated onto the first upper surface 310a of the first memory die 300. The irradiated light RU may have a wavelength for measuring the distances between the first and second memory dies 300, 400 and the buffer die 200. The irradiated light R0 may be emitted from the time domain spectroscopy (TDS). The irradiated light R0 may include the wavelength of infrared radiation.

Then, the light may pass from the scribe lane region SR to the first light transmitting region 326 disposed in the first active layer 320 of the first memory die 300 (S142), and the irradiated light R0 may pass from the scribe lane region SR to the second light transmitting region 426 disposed in the second active layer 420 of the second memory die 400 (S143).

In example embodiments, the first active layer 320 of the first memory die 300 may include the first light transmitting region 326. The second active layer 420 of the second memory die 400 may include the second light transmitting region 426.

As illustrated in FIGS. 18 and 19, the first and second light transmitting regions 326, 426 may transmit the irradiated light R0. In some embodiments, metal regions of the first and second memory dies 300, 400 may reflect the irradiated light R0. The irradiated light R0 may not pass through the first memory die 300 disposed below the second memory die 400 in the metal region.

For example, the first and second light transmitting regions 326, 426 may be regions that do not include the metal materials in the first and second active layers 320, 420. The metal material may include aluminum (Al), copper (Cu), tin (Sn), nickel (Ni), gold (Au), platinum (Pt), or an alloy thereof.

Then, the light reflected from the second memory die 400 disposed below the first memory die 300 may be obtained (S144), and the light reflected from the buffer die 200 disposed below the second memory die 400 may be obtained (S145).

In example embodiments, the light may be reflected from the first and second memory dies 300, 400 and the buffer die 200.

As illustrated in FIG. 20, the irradiated light R0 may be reflected from the first upper surface 310a and the first lower surface 310b of the first memory die 300. First thickness T1 of the first memory die 300 may be obtained through the light R1 reflected from the first upper surface 310a and the light R2 reflected from the first lower surface 310b. The reflected lights R1, R2 may be obtained by the time domain spectroscopy (TDS).

The light may be reflected from the second upper surface 410a and the second lower surface 410b of the second memory die 400. The light may pass through the first light transmitting region 326 of the first memory die 300 to reach the second upper surface 410a of the second memory die 400. Second thickness T2 of the second memory die 400 may be obtained through the light R3 reflected from the second upper surface 410a and the light R4 reflected from the second lower surface 410b. A first distance L1 between the first and second memory dies 300, 400 may be obtained through light R2 reflected from the first lower surface 310b of the first memory die 300 and light R3 reflected from the second upper surface 410a of the second memory die 400. The reflected lights R2, R3 may be obtained by the time domain spectroscopy.

The light may be reflected from the upper surface of the buffer die 200. The light may reach the upper surface of the buffer die 200 after sequentially passing through the first light transmitting region 326 of the first memory die 300 and the second light transmitting region 426 of the second memory die 400. A second distance L2 between the second memory die 400 and the buffer die 200 may be obtained through the light R4 reflected from the second lower surface 410b of the second memory die 400 and the light R5 reflected from the upper surface of the buffer die 200. The reflected lights R4, R5 may be obtained by the time domain spectroscopy.

Then, the distance L1 between the first and second memory dies 300, 400 may be measured through the obtained lights R2, R3 (S146), and the distance L2 between the second memory die 400 and the buffer die 200 may be measured through the obtained lights R4, R5 (S147).

In example embodiments, the light reflected from the buffer die 200 and the first and second memory dies 300, 400 may be analyzed by the time domain spectroscopy.

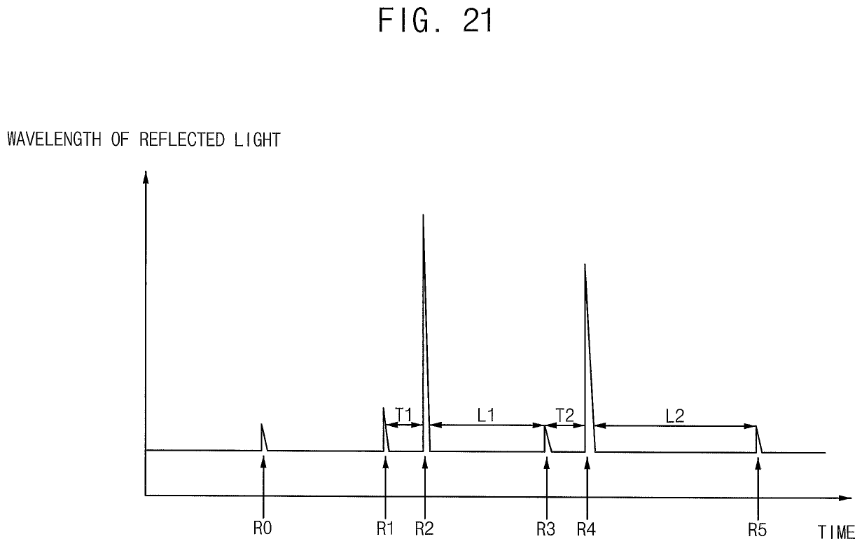

As illustrated in FIG. 21, the time domain spectroscopy may analyze the wavelengths of the reflected lights. The time domain spectroscopy may analyze the wavelength of the reflected light according to time.

The time domain spectroscopy may obtain the first thickness T1 of the first memory die 300 through the light R1 reflected from the first upper surface 310a. of the first memory die 300 and the light R2 reflected from the first lower surface 310b of the first memory die 300.

The time domain spectroscopy may obtain the second thickness T2 of the second memory die 400 through the light R3 reflected from the second upper surface 410a of the second. memory die 400 and the light R4 reflected from the second lower surface 410b of the second memory die 400.

The time domain spectroscopy may obtain the first distance L1 between the first and second memory dies 300, 400 through the light R2 reflected from the first lower surface 310b of the first memory die 300 and the light R3 reflected from the second upper surface 410a of the second memory die 400.

The time domain spectroscopy may acquire the second distance L2 between the second memory die 400 and the buffer die 200 through the light R4 reflected from the second lower surface 410b of the second memory die 400 and the light R5 reflected from the upper surface of the buffer die 200.

As described above, the irradiated light R0 irradiated to the semiconductor device 100 may pass through the first light transmitting region 326 to reach the second memory die 400. The distance L1 between the first and second memory dies 300, 400 may be directly measured through the light R2 reflected from the first memory die 300 and the light R3 reflected from the second memory die 400. The distance L2 between the second memory die 400 and the buffer die 200 may be directly measured through the light R4 reflected from the second memory die 400 and the light R5 reflected from the buffer die 200. Since the respective distances L1, L2 between the buffer die 200 and the first and second memory dies 300, 400 can be measured directly, it is possible to accurately analyze the distance error occurring in the semiconductor manufacturing process such as thermal compression bonding process.

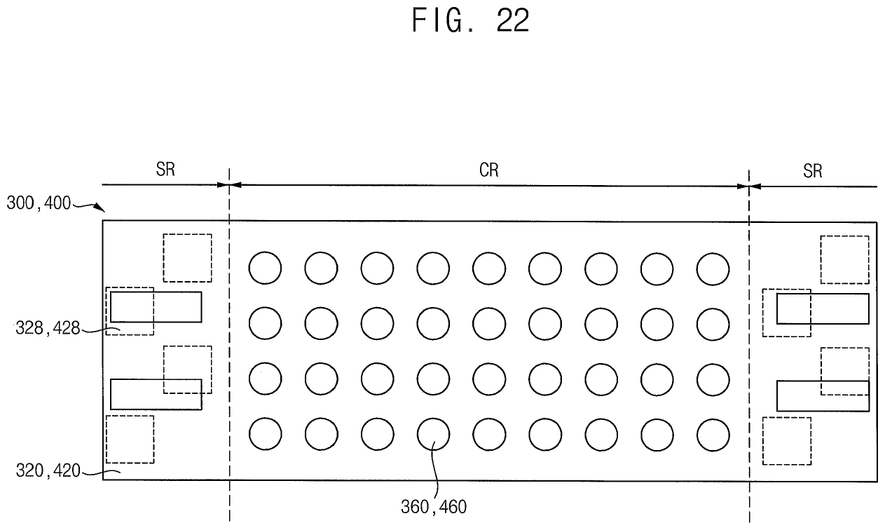

FIG. 22 is a plan view illustrating a memory die of a semiconductor package having light transmitting spots in a light transmitting region in accordance with example embodiments. The semiconductor package may be substantially the same as or similar to the semiconductor package described with reference to FIGS. 1 to 4 except for a configuration of a light transmitting region. Thus, same or similar components may be denoted by the same or similar reference numerals, and repeated descriptions of the same components will be omitted.

As illustrated in FIGS. 1 to 4 and 22, the first and second light transmitting regions 326, 426 of the first and second memory dies 300, 400 may include light transmitting spots for passing the light through.

The first light transmitting region 326 of the first memory die 300 may include a plurality of first light transmitting spots 328 irregularly distributed in the first active layer 320. The first light transmitting spots 328 may be disposed in the scribe lane region SR. The first light transmitting spots 328 may be cut and removed from the semiconductor device 100 during a process.

The second light transmitting region 426 of the second memory die 400 may include a plurality of second light transmitting spots 428 irregularly distributed in the second active layer 420. The second light transmitting spots 428 may be disposed in the scribe lane region SR. The second light transmitting spots 428 may be cut and removed from the semiconductor device 100 during the process.

The first light transmitting spots 328 of the first memory die 300 and the second light transmitting spots 428 of the second memory die 400 may have regions overlapping each other when viewed in a plan view. The light may pass through the semiconductor device 100 including the overlapping regions in the vertical direction. The light may be reflected by the first and second memory dies 300, 400 and the buffer die 200, respectively, while passing through the overlapping regions, and each of the distances between the first and second memory dies 300, 400 and the buffer die 200 may be measured through the reflected lights.

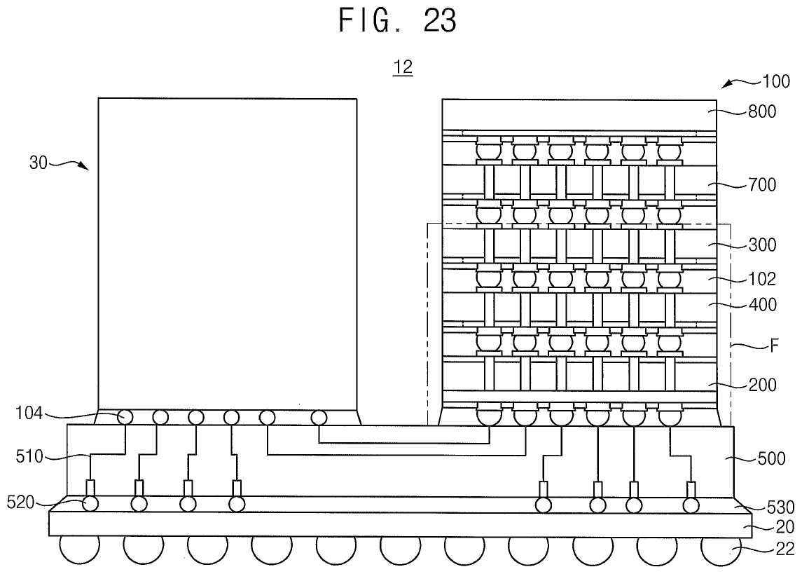

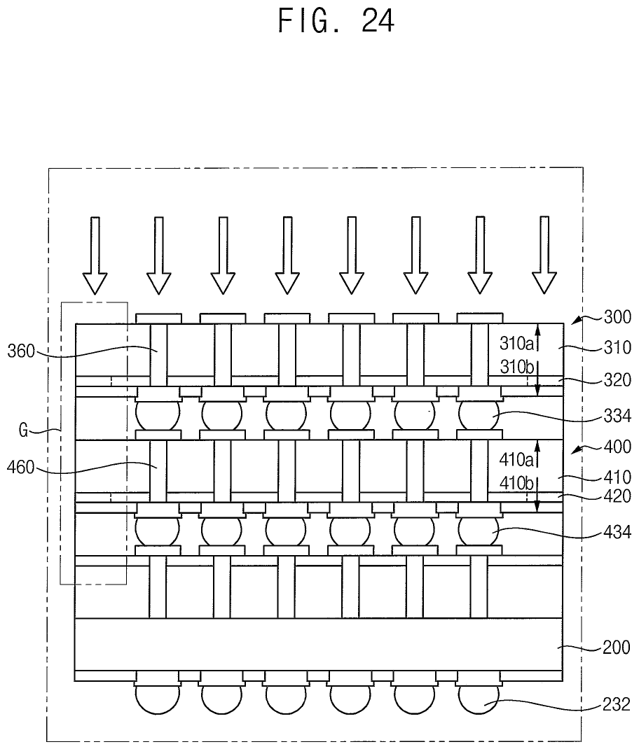

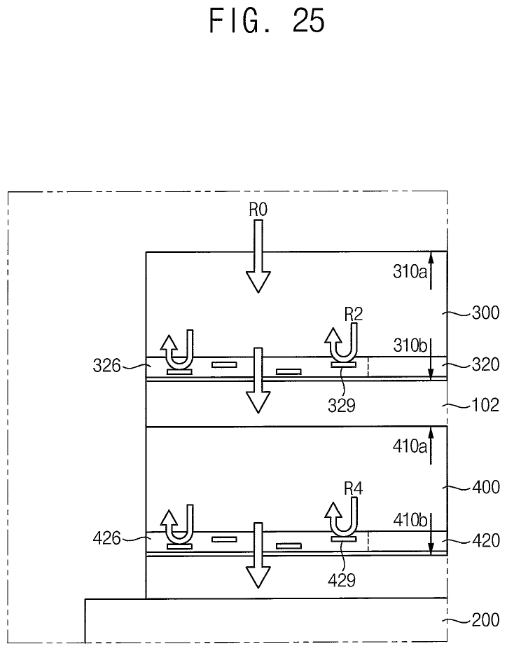

FIG. 23 is a cross-sectional view illustrating a semiconductor package in accordance with example embodiments. FIG. 24 is a detailed cross-sectional view illustrating portion ‘F’ in FIG. 23. FIG. 25 is a detailed cross-sectional view illustrating portion ‘G’ in FIG. 24. The semiconductor package may be substantially the same as or similar to the semiconductor package described with reference to FIGS. 1 to 4 except for a configuration of a reflective pad. Thus, same or similar components may be denoted by the same or similar reference numerals, and repeated descriptions of the same components will be omitted.

Referring to FIGS. 23 to 25, the semiconductor package 12 may include the package substrate 20, the electronic component 30, and the semiconductor device 100 respectively disposed on the package substrate 20. The semiconductor device 100 may include the buffer die 200, the second memory die 400 stacked on the buffer die 200 in the vertical direction, and The first memory die 300 stacked in the vertical direction on the second memory die 400.

In example embodiments, the first active layer 320 of the first memory die 300 may have the first light transmitting region 326 for passing the irradiated light R0 incident from the first upper surface 310a to the first lower surface 310b. The first light transmitting region 326 may be disposed in the scribe lane region SR in which the first memory die 300 may be cut.

The first memory die 300 may include first reflective pads 329 for reflecting a portion of the irradiated light R0. The first reflective pad 329 may generate total reflection of the irradiated light R0. Since the first reflective pad 329 reflects a portion of the irradiated light R0, the time domain spectrometer may more accurately measure the light R2 reflected from the first lower surface 310b of the first memory die 300.

In example embodiments, the second active layer 420 of the second memory die 400 may have the second light transmitting region 426 for passing the light R3 incident from the second upper surface 410a to the second lower surface 410b. The second light transmitting region 426 may be disposed in the scribe lane region SR in which the second memory die 400 may be cut.

The second memory die 400 may include second reflective pads 429 for reflecting a portion of the light R3. The second reflective pad 429 may generate total reflection of the light R3. Since the second reflective pad 429 reflects a portion of the light R3, the time domain spectrometer may more accurately measure the light R4 reflected from the second lower surface 410b of the second memory die 400.

For example, the first and second reflective pads 329, 429 may include a metal material that reflects the irradiated light R0, R3. The metal material may include aluminum (A1), copper (Cu), tin (Sn), nickel (Ni), gold (Au), platinum (Pt), or an alloy thereof.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A method of manufacturing a semiconductor package, comprising:
disposing a buffer die on a support carrier;
forming a plurality of memory dies, each of the plurality of memory dies haying a body layer and an active layer on a surface of the body layer, wherein the body layer includes a light transmitting region;
stacking the plurality of memory dies on the buffer die in a vertical direction to form a semiconductor device;
measuring respective distances between the buffer die and the plurality of memory dies by irradiating light on the semiconductor device in the vertical direction; and
forming a molding member encapsulating the semiconductor device,
wherein measuring the respective distances between the buffer die and the plurality of memory dies includes:
irradiating first light on a first memory die positioned at an uppermost position among the plurality of memory dies, the first memory die having a first body layer and a first active layer, wherein the first body layer includes a first light transmitting region; and
measuring a distance between the first memory die and a second memory die through first detected light, wherein the second memory die is positioned immediately below the first memory die among the plurality of memory dies, and wherein the first detected light is formed by the first light sequentially passing through the first light transmitting region in a thickness direction of the first layer, being incident on the second memory die, and reflected from the second memory die.

2. The method of claim 1, wherein measuring the respective distances between the buffer die and the plurality of memory dies further includes:
irradiating second light on the second memory die; and
measuring a distance between the second memory die and the buffer die through second detected light, wherein the second detected light is formed by the second light sequentially passing through a. second light transmitting region of the second memory die, being incident on the buffer die, and reflected from the buffer die.

3. The method of claim 2, wherein measuring the respective distances between the buffer die and the plurality of memory dies further includes:
measuring a distance between the second memory die and a third memory die through third detected light, wherein the third memory die is positioned immediately below the second memory die among the plurality of memory dies, and wherein the third detected light is formed by the second light passing through the second light transmitting region of the second memory die, being incident on the third memory die, and reflected from the third memory die.

4. The method of claim 3, wherein the first light transmitting region and the second light transmitting region at least partially overlap each other in a plan view.

5. The method of claim 1, wherein the first light transmitting region extends horizontally from an outer surface of the first memory die in the first active layer to have a predetermined length.

6. The method of claim 5, wherein the predetermined length is within a range of 25 μm to 35 μm.

7. The method of claim 1, wherein the light includes infrared radiation wavelength.

8. The method of claim 1, wherein the first light transmitting region includes a plurality of light transmitting spots within the first active layer.

9. The method of claim 1, wherein the first light transmitting region includes a plurality of reflective pads provided in the first active layer to reflect a portion of the light.

10. The method of claim 1, wherein the first memory die further includes a die region and a scribe lane region surrounding the die region in a plan view, the first light transmitting region provided in the scribed lane region, and
the method further comprising:
cutting the molding member along the scribe lane region to form the semiconductor package.

11. A method of manufacturing a semiconductor package, comprising:
disposing a semiconductor device on a support carrier, wherein the semiconductor includes a buffer die and a plurality of memory dies vertically stacked on the buffer die;
irradiating light on a first memory die positioned at an uppermost position among the plurality of memory dies;
passing the light through a first light transmitting region in a first scribe lane region of a first active layer of the first memory die in a thickness direction of the first active layer;
detecting first light reflected from a second memory die positioned immediately below the first memory die among the plurality of memory dies; and
measuring a distance between the first and second memory dies through the detected first light.

12. The method of claim 11, further comprising:
passing the light through a second light transmitting region in a second scribe lane region of a second active layer of the second memory die;
detecting second light reflected from the buffer die positioned below the second memory die; and
measuring a distance between the second memory die and the buffer die through the detected second light.

13. The method of claim 12, further comprising:
detecting third light reflected from a third memory die positioned immediately below the second memory die among the plurality of memory dies; and
measuring a distance between the second and third memory dies through the detected light.

14. The method of claim 13, wherein the first light transmitting region and the second light transmitting region at least partially overlap each other in a plan view.

15. The method of claim 11, wherein the first light transmitting region extends horizontally from an outer surface of the first memory die in the first active layer to have a predetermined length.

16. The method of claim 15, wherein the predetermined length is within a range of 25 μm to 35 μm.

17. The method of claim 11, wherein the light includes infrared radiation wavelength.

18. The method of claim 11, wherein the first light transmitting region includes a plurality of light transmitting spots within the first active layer.

19. The method of claim 11, wherein the first light transmitting region includes a plurality of reflective pads that are disposed in the first active layer o reflect a portion of the light.

20. A semiconductor package, comprising:
a buffer die;
a second memory die vertically stacked on the buffer die, the second memory die having a second upper surface and a second lower surface opposite to each other, the second memory die having a second active layer provided on the second lower surface and a second light transmitting region that is configured to pass light incident from the second upper surface to the buffer die; and
a first memory die vertically stacked on the second memory die, the first memory die having a first upper surface and a first lower surface opposite to each other; the first memory die having a first active layer provided on the first lower surface and a first light transmitting region configured to pass light incident from the first upper surface to the second memory die.
